(19) United States
(12) Patent Application Publication
(10) Pub. No.: US 2026/0073984 A1
(43) Pub. Date: Mar. 12, 2026

(54) MEMORY DEVICE, MEMORY SYSTEM INCLUDIMG THE MEMORY DEVICE, AND OPERATING METHOD OF THE MEMORY SYSTEM

(71) Applicant: SK hynix Inc., Icheon-si (KR)

(72) Inventors: Min Su KANG, Icheon-si (KR); Gap Sok DO, Icheon-si (KR)

(21) Appl. No.: 19/240,431

(22) Filed: Jun. 17, 2025

(30) Foreign Application Priority Data
Sep. 12, 2024 (KR) 10-2024-0124573

(51) Int. Cl. G11C 13/00

(52) U.S. Cl. CPC G11C 13/004; G11C 13/0038

(57) ABSTRACT

A memory device includes a memory cell array including memory cells, a first voltage selection circuit suitable for supplying one of a high voltage and a low voltage to one end of the memory cell array in response to a flag signal indicating a forward read operation or a reverse read operation in a read mode, a logic value of the flag signal being determined based on read count information, a second voltage selection circuit suitable for supplying the other voltage of the high voltage and the low voltage to the other end of the memory cell array in response to the flag signal in the read mode, and a read circuit coupled to one of the one end and the other end of the memory cell array and reading data stored in a memory cell selected from the memory cells in the read mode.

### CROSS-REFERENCE TO RELATED APPLICATION(S)

This application claims priority under 35 U.S.C. § 119 to Korean Patent Application No. 10-2024-0124573, filed on Sep. 12, 2024, the disclosure of which is incorporated herein by reference in its entirety.

### BACKGROUND

### 1. Field

Various embodiments of the present disclosure relate to semiconductor design techniques, and more particularly, to a memory device supporting a read mode, a memory system including the memory device, and an operating method of the memory system.

### 2. Description of the Related Art

A memory device is broadly categorized into volatile memory devices and non-volatile memory devices. A volatile memory device is a memory device in which stored data is lost when the power supply is cut off. In contrast, a non-volatile memory device retains stored data even when the power supply is cut off.

A memory cell in a memory device may have a uniform logic state based on physical or chemical characteristics of a material constituting the memory cell. A non-volatile memory device that includes a memory cell formed of a chalcogenide-based material may have a slower operating speed but larger capacity or integration than a dynamic random access memory (DRAM), and a faster operating speed but smaller capacity or integration than a NAND flash memory.

In a memory device, read disturbance may be generated in a read mode. The read disturbance refers to a phenomenon in which a data value or logic value of a memory cell, selected from among a plurality of memory cells, is unintentionally changed due to structural and/or operational characteristics of the memory device in the read mode.

FIG. 1 illustrates a graph for describing the read disturbance according to prior art.

Referring to FIG. 1, when a specific memory cell among a plurality of memory cells is in a high resistance state, such as a RESET state, threshold voltages of the plurality of memory cells have a normal distribution VTH_N. However, when read data is repeatedly read from the plurality of memory cells, the threshold voltages deteriorate, resulting in an abnormal distribution VTH_A.

In the abnormal distribution VTH_A, some memory cells (shown in the hatched portion), each having a threshold voltage lower than a read voltage VRD, are turned on by the read voltage VRD during a read operation. These memory cells change from the high resistance state, such as the RESET state, to a low resistance state, such as a SET state. In this way, this unintended change in a resistance state of a memory cell during the read operation is referred to as the read disturbance.

### SUMMARY

Various embodiments of the present disclosure are directed to a memory device capable of suppressing read disturbance in a read mode, a memory system including the memory device, and an operating method of the memory system.

In accordance with an embodiment of the present disclosure, a memory device may include: a memory cell array including a plurality of memory cells; a first voltage selection circuit suitable for supplying one of a high voltage and a low voltage to one end of the memory cell array in response to a flag signal indicating a forward read operation or a reverse read operation in a read mode, a logic value of the flag signal being determined based on read count information; a second voltage selection circuit suitable for supplying the other voltage of the high voltage and the low voltage to the other end of the memory cell array in response to the flag signal in the read mode; and a read circuit coupled to one of the one end and the other end of the memory cell array and suitable for reading data stored in a memory cell selected from the plurality of memory cells in the read mode.

In accordance with an embodiment of the present disclosure, a memory system may include: a control device suitable for generating a flag signal indicating a forward read operation or a reverse read operation based on read count information; and a memory device suitable for changing a direction of a cell current flowing through a memory cell selected from a plurality of memory cells within a memory cell array, according to the forward read operation or the reverse read operation, and outputting read data corresponding to the cell current to the control device, based on the flag signal and a read command signal.

In accordance with an embodiment of the present disclosure, an operating method of a memory system may include: causing a cell current to flow in a first direction through a memory cell selected from a plurality of memory cells in a memory cell array, according to a forward read operation when read count information corresponding to the selected memory cell is N times or less (where N is a natural number greater than or equal to 1); causing the cell current to flow in a second direction through the selected memory cell according to a reverse read operation when the read count information corresponding to the selected memory cell is greater than N but 2N times or less, the first direction being opposite to the second direction; and reading data stored in the selected memory cell based on the cell current and a reference current.

### BRIEF DESCRIPTION OF THE DRAWINGS

FIG. 1 is a graph for describing read disturbance according to prior art.

FIG. 2 illustrates a memory system in accordance with an embodiment of the present disclosure.

FIG. 3 illustrates an example of a memory device illustrated in FIG. 2.

FIG. 4 is a simplified diagram illustrating a coupling structure between first and second voltage selection circuits illustrated in FIG. 3 and a memory cell described with reference to FIG. 3.

FIG. 5 is a flowchart illustrating an operating method of a memory system in accordance with an embodiment of the present disclosure.

FIG. 6 is a simplified diagram for additionally describing a forward read operation described with reference to FIG. 5.

FIG. 7 is a simplified diagram for additionally describing a reverse read operation described with reference to FIG. 5.

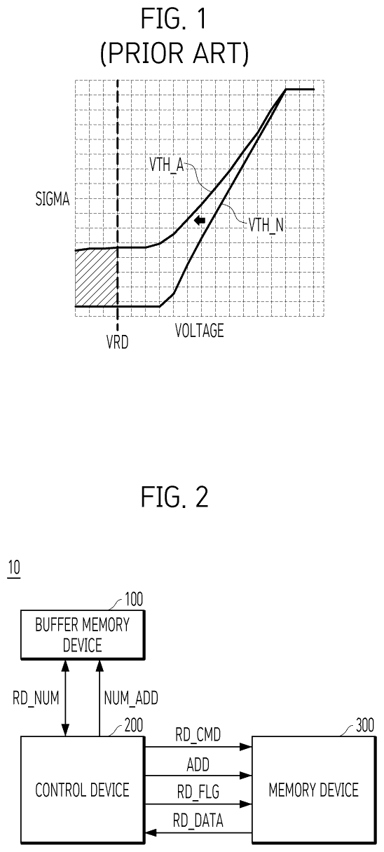

### DETAILED DESCRIPTION

Various embodiments of the present disclosure are described below with reference to the accompanying drawings, in order to describe in detail the embodiments of the present disclosure so that those with ordinary skill in art to which the present disclosure pertains may easily carry out the technical spirit of the present disclosure.

It will be understood that when an element is described as being “connected to” or “coupled to” another element, the connection may be direct, or it may be indirect through one or more intervening elements, either physically or electrically. In addition, it will also be understood that the terms “comprises,” “comprising,” “includes,” and “including” when used in this specification do not preclude the presence of one or more other elements, but may further include or have the one or more other elements, unless otherwise mentioned. In the description throughout the specification, some components are described in singular forms, but the present disclosure is not limited thereto, and it will be understood that the components may be formed in plural.

FIG. 2 illustrates a memory system 10 in accordance with an embodiment of the present disclosure.

Referring to FIG. 2, the memory system 10 may include a buffer memory device 100, a control device 200, and a memory device 300.

The buffer memory device 100 may store read count information RD_NUM. For example, the buffer memory device 100 may store the read count information RD_NUM based on address information NUM_ADD. The read count information RD_NUM may be tracked for each memory region or memory group within a memory cell array, as described below. The memory region may correspond to a page or a block of the memory cell array. The address information NUM_ADD may correspond to an address indicating the memory region.

The control device 200 may generate a read command signal RD_CMD and an address signal ADD in a read mode. The control device 200 may receive read data RD_DATA from the memory device 300 in the read mode. For example, the control device 200 may be a host or a memory controller that mediates communication between the host and the memory device 300.

The control device 200 may generate the read count information RD_NUM representing the number of times the read command signal RD_CMD is generated or received. For example, the control device 200 may update the read count information RD_NUM each time it generates the read command signal RD_CMD. It may also initialize or reset the read count information RD_NUM when the read count information RD_NUM reaches or exceeds a predetermined threshold, e.g., ‘2N’ times, where ‘N’ is a natural number greater than or equal to 1.

The control device 200 may also generate a flag signal RD_FLG to indicate a forward read operation or a reverse read operation based on the read count information RD_NUM. For example, the control device 200 may generate the flag signal RD_FLG indicating the forward read operation when the read count information RD_NUM is less than or equal to ‘N’ times, and the reverse read operation when the read count information RD_NUM exceeds the ‘N’ times but is less than or equal to the ‘2N’ times. In other words, the control device 200 may toggle a logic level of the flag signal RD_FLG whenever the read count information RD_NUM reaches the ‘N’ times. Additionally, the control device 200 may initialize or reset the read count information RD_NUM whenever the read count information RD_NUM reaches the ‘2N’ times.

The memory device 300 outputs the read data RD_DATA to the control device 200 based on the read command signal RD_CMD, the address signal ADD, and the flag signal RD_FLG. For example, the memory device 300 may change a direction of a cell current flowing through a selected memory cell in the memory cell array, as described below, based on whether the forward read operation or the reverse read operation is performed. It then generates the read data RD_DATA corresponding to the cell current. During the forward read operation, the read data RD_DATA may have an original data value, while during the reverse read operation, it may have an inverted value of the original data value, because the memory device 300 has a characteristic in which the data value of the memory cell changes based on the direction of the cell current. During the reverse read operation, the inversion of the read data RD_DATA may be performed by the memory device 300 or the control device 200, depending on the design configuration.

In FIG. 2, the buffer memory device 100 and the control device 200 are separate from the memory device 300. However, embodiments are not limited thereto. In another embodiment, the buffer memory device 100 and the control device 200 may be implemented to be included in the memory device 300. In this embodiment, the buffer memory device 100 may be a buffer memory that is either integrated within the memory cell array or configured separately from the memory cell array.

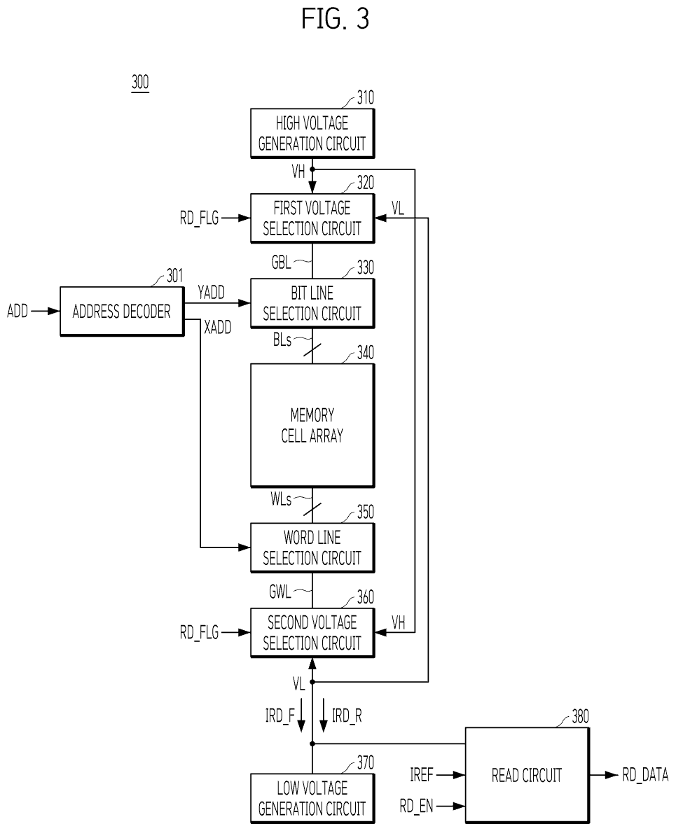

FIG. 3 illustrates an example of the memory device 300 illustrated in FIG. 2.

Referring to FIG. 3, the memory device 300 may include an address decoder 301, a high voltage generation circuit 310, a first voltage selection circuit 320, a bit line selection circuit 330, a memory cell array 340, a word line selection circuit 350, a second voltage selection circuit 360, a low voltage generation circuit 370, and a read circuit 380.

In the read mode, the address decoder 301 may receive the address signal ADD and generate a bit line selection signal YADD and a word line selection signal XADD, which correspond to the selected memory cell.

The high voltage generation circuit 310 may generate a high voltage VH in the read mode. For example, the high voltage VH may be a positive voltage.

The low voltage generation circuit 370 may generate a low voltage VL in the read mode. For example, the low voltage VL may be a ground voltage or a negative voltage.

In the read mode, the first voltage selection circuit 320 may receive the flag signal RD_FLG and supply one of the high voltage VH and the low voltage VL to one end of the memory cell array 340 based on the flag signal RD_FLG. More specifically, the first voltage selection circuit 320 may supply one of the high voltage VH and the low voltage VL to a global bit line GBL coupled to the one end of the memory cell array 340, based on the flag signal RD_FLG in the read mode. For example, the first voltage selection circuit 320 may supply the high voltage VH to the global bit line GBL during the forward read operation and supply the low voltage VL to the global bit line GBL during the reverse read operation.

In the read mode, the bit line selection circuit 330 may receive the bit line selection signal YADD and couple the global bit line GBL to a bit line selected from among a plurality of bit lines BLs based on the bit line selection signal YADD. The bit line selection circuit 330 may supply the one voltage to the memory cell array 340 through the global bit line GBL and the selected bit line.

In the read mode, the second voltage selection circuit 360 may receive the flag signal RD_FLG and supply the other voltage of the high voltage VH and the low voltage VL to the other end of the memory cell array 340 based on the flag signal RD_FLG. More specifically, the second voltage selection circuit 360 may supply the other voltage of the high voltage VH and the low voltage VL to a global word line GWL coupled to the other end of the memory cell array 340, based on the flag signal RD_FLG in the read mode.

In the read mode, the word line selection circuit 350 may receive the word line selection signal XADD and couple the global word line GWL to a word line selected among a plurality of word lines WLs based on the word line selection signal XADD. The word line selection circuit 350 may supply the other voltage to the memory cell array 340 through the global word line GWL and the selected word line.

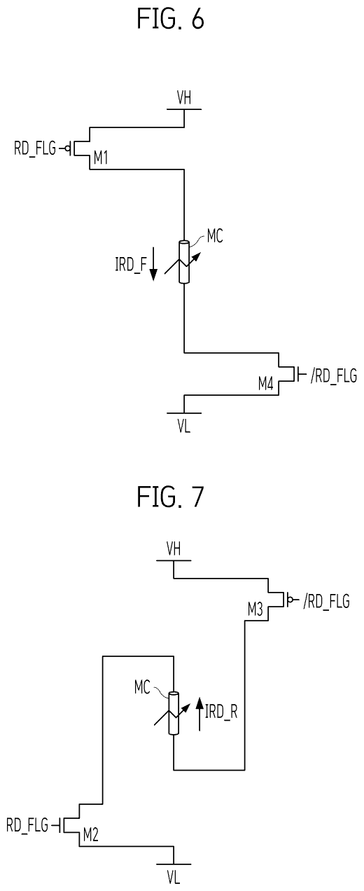

The memory cell array 340 may include the plurality of memory cells disposed at intersections of the plurality of bit lines BLs and the plurality of word lines WLs. The selected memory cell among the plurality of memory cells may be coupled between the selected bit line and the selected word line. As described above, the cell current may flow through the selected memory cell in the read mode. For example, in the forward read operation, the cell current may flow in one direction, e.g., a forward direction, through the selected memory cell (refer to FIG. 6). In the revers read operation, the cell current may flow in the other direction, e.g., a reverse direction, through the selected memory cell (refer to FIG. 7). Hereinafter, the cell current flowing in one direction is referred to as a ‘forward current IRD_F,’ and the cell current flowing in the other direction is referred to as a ‘reverse current IRD_R.’ For example, each of the plurality of memory cells may include a selector only memory (SOM) element. The SOM element may include a selection element layer. The selection element layer may exhibit a threshold switching characteristic, wherein it blocks or substantially limits current flow through the memory cell when a voltage difference across the selector element layer is less than a predetermined threshold value and allows the current flowing through the memory cell to increase abruptly when the voltage difference exceeds the predetermined threshold value. The threshold value may be referred to as a threshold voltage and determine whether the selection element layer is in a turned-on state or a turned-off state.

The selection element layer may include various materials, such as a diode, an ovonic threshold switching (OTS) material (e.g., a chalcogenide-based material), a mixed ionic electronic conducting (MIEC) material (e.g., a metal-containing chalcogenide-based material), a metal insulator transition (MIT) material (e.g., NbO₂ or VO₂), or a tunneling dielectric layer having a relatively wide band gap (e.g., SiO₂ or Al₂O₃). In particular, the selection element layer may include a material containing a plurality of trap sites capable of trapping charges, such as an OTS material.

The SOM element, incorporating the selection element layer, may simultaneously function as both a memory element and a selection element. In this configuration, the SOM element may operate as a self-selecting memory. More specifically, the self-selecting memory may exhibit a variable resistance characteristic enabling it to store data by switching between different resistance states based on the voltage difference applied across a selected memory cell. At the same time, the self-selecting memory may exhibit a threshold switching characteristic, wherein it blocks or substantially limits current flow through the selected memory cell when the voltage difference across the selected memory cell is less than the predetermined threshold value and allows a current flowing through the selected memory cell to increase abruptly when the voltage difference exceeds the predetermined threshold value. The predetermined threshold value may be referred to as a threshold voltage and determine whether the self-selecting memory is turned on or turned off.

The threshold voltage may vary depending on a resistance state of the self-selecting memory. That is, the self-selecting memory may have different threshold voltages corresponding to its resistance states. For example, when the self-selecting memory is in a low resistance state, it may have a first threshold voltage. On the other hand, when the self-selecting memory is in a high resistance state, it may have a second threshold voltage that is different from the first threshold voltage. Accordingly, this characteristic enables the self-selecting memory to simultaneously function as both the memory element and the selection element.

The read circuit 380 may be coupled to the other end of the memory cell array 340. More specifically, the read circuit 380 may be coupled to an output terminal of the low voltage generation circuit 370. The read circuit 380 may be enabled in response to a read enable signal RD_EN. Although not illustrated, the read enable signal RD_EN may be generated based on the read command signal RD_CMD. In the read mode, the read circuit 380 may detect data stored in the selected memory cell and output the detected data as the read data RD_DATA. For example, the read circuit 380 may compare the forward current IRD_F with a reference current IREF and generate the read data RD_DATA corresponding to the comparison result during the forward read operation, and may compare the reverse current IRD_R with the reference current IREF and generate the read data RD_DATA corresponding to the comparison result during the reverse read operation.

In an embodiment, it is described as an example that the read circuit 380 is coupled to the other end of the memory cell array 340, but the present disclosure is not necessarily limited thereto. In another embodiment, the read circuit 380 may be coupled to one end of the memory cell array 340, for example, an output terminal of the high voltage generation circuit 310.

In an embodiment, it is described as an example that the read circuit 380 is a current comparison-based circuit, but the present disclosure is not necessarily limited thereto. In another embodiment, the read circuit 380 may be a voltage comparison-based circuit. For example, the read circuit 380 may compare a voltage corresponding to the forward current IRD_F with a reference voltage corresponding to the reference current IREF, or compare a voltage corresponding to the reverse current IRD_R with the reference voltage.

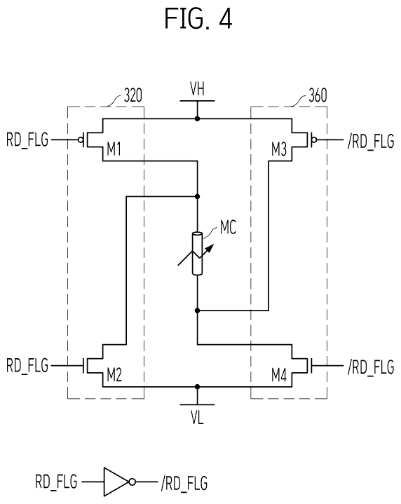

FIG. 4 is a simplified diagram illustrating a coupling structure between the first and second voltage selection circuits 320 and 360 illustrated in FIG. 3 and a memory cell described with reference to FIG. 3.

Referring to FIG. 4, the first voltage selection circuit 320 may include a first coupling portion M1 and a second coupling portion M2.

The first coupling portion M1 may be coupled between an output terminal of the high voltage VH and one end of the memory cell MC, that is, the global bit line GBL. The first coupling portion M1 may electrically couple the output terminal of the high voltage VH to the one end of the memory cell MC during the forward read operation and electrically decouple the output terminal of the high voltage VH from the one end of the memory cell MC during the reverse read operation, in response to the flag signal RD_FLG. For example, the first coupling portion M1 may include a PMOS transistor having a gate terminal that receives the flag signal RD_FLG, a source terminal coupled to the output terminal of the high voltage VH, and a drain terminal coupled to the one end of the memory cell MC.

The second coupling portion M2 may be coupled between an output terminal of the low voltage VL and the one end of the memory cell MC, that is, the global bit line GBL. The second coupling portion M2 may electrically couple the output terminal of the low voltage VL to the one end of the memory cell MC during the reverse read operation and electrically decouple the output terminal of the low voltage VL from the one end of the memory cell MC during the forward read operation, in response to the flag signal RD_FLG. For example, the second coupling portion M2 may include an NMOS transistor having a gate terminal that receives the flag signal RD_FLG, a source terminal coupled to the output terminal of the low voltage VL, and a drain terminal coupled to the one end of the memory cell MC.

The second voltage selection circuit 360 may include a third coupling portion M3 and a fourth coupling portion M4.

The third coupling portion M3 may be coupled between the output terminal of the high voltage VH and the other end of the memory cell MC, that is, the global word line GWL. The third coupling portion M3 may electrically couple the output terminal of the high voltage VH to the other end of the memory cell MC during the reverse read operation and electrically decouple the output terminal of the high voltage VH from the other end of the memory cell MC during the forward read operation, in response to an inverted flag signal/RD_FLG. For example, the third coupling portion M3 may include a PMOS transistor having a gate terminal that receives the inverted flag signal/RD_FLG, a source terminal coupled to the output terminal of the high voltage VH, and a drain terminal coupled to the other end of the memory cell MC.

The fourth coupling portion M4 may be coupled between the output terminal of the low voltage VL and the other end of the memory cell MC, that is, the global word line GWL. The fourth coupling portion M4 may electrically couple the output terminal of the low voltage VL to the other end of the memory cell MC during the forward read operation and electrically decouple the output terminal of the low voltage VL from the other end of the memory cell MC during the reverse read operation, in response to the inverted flag signal/RD_FLG. For example, the fourth coupling portion M4 may include an NMOS transistor having a gate terminal that receives the inverted flag signal/DR_FLG, a source terminal coupled to the output terminal of the low voltage VL, and a drain terminal coupled to the other end of the memory cell MC.

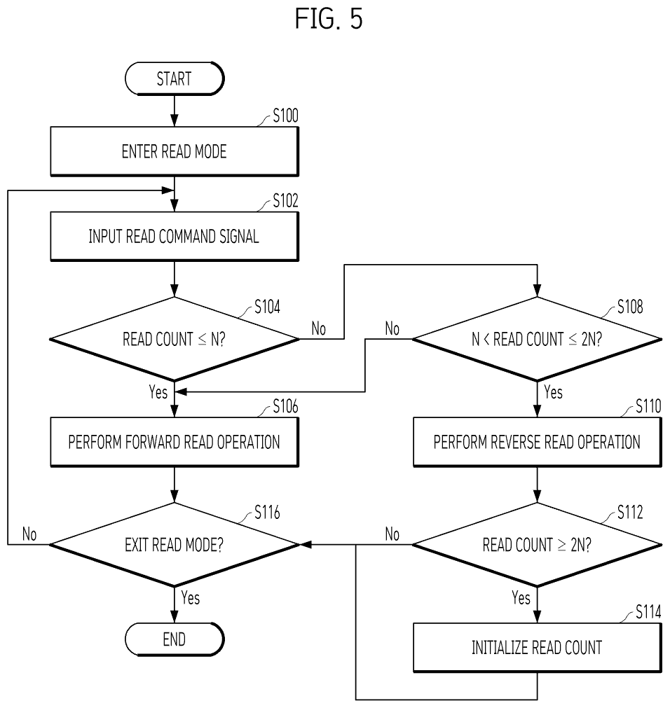

Hereinafter, an operation of the memory system 10, which has the above-described configuration illustrated in FIGS. 2 to 4, will be described with reference to FIGS. 5 to 7.

FIG. 5 is a flowchart illustrating an operating method of the memory system 10 illustrated in FIGS. 2 and 3.

Referring to FIGS. 2, 3, and 5, the control device 200 may generate the read command signal RD_CMD in the read mode in step S100 and S102. The control device 200 may update the read count information RD_NUM when generating the read command signal RD_CMD. The read count information RD_NUM may be tracked for each memory region or memory group of the memory cell array 340. The memory region may correspond to a page or block of the memory cell array 340.

The control device 200 may generate the flag signal RD_FLG based on the read count information RD_NUM in the read mode. The flag signal RD_FLG may indicate whether the forward read operation or the reverse read operation is performed. For example, the control device 200 may toggle the logic level of the flag signal RD_FLG each time the read count information RD_NUM reaches ‘N’ times, where ‘N’ is a natural number greater than or equal to 1.

When the read count information RD_NUM for a memory region (hereinafter referred to as a ‘selected memory region’), to which a memory cell selected from among a plurality of memory cells included in the memory cell array 340 belongs, is ‘N’ times or less, the control device 200 may generate the flag signal RD_FLG corresponding to the forward read operation in step S104. When the read count information RD_NUM for the selected memory region is ‘N’ times or less, the memory device 300 may generate the forward current IRD_F that flows in one direction through the selected memory cell according to the forward read operation in step S106. For example, the memory device 300 may generate the forward current IRD_F during the forward read operation while performing the read operation on the selected memory region between one and 200 times (i.e., ‘N’ is ‘200’).

During the forward read operation, the read circuit 380 may compare the forward current IRD_F with the reference current IREF and generate the read data RD_DATA corresponding to the comparison result.

When the read count information RD_NUM for the selected memory region is greater than the ‘N’ times and less than or equal to ‘2N’ times, the control device 200 may generate the flag signal RD_FLG corresponding to the reverse read operation in step S108. When the read count information RD_NUM for the selected memory region is greater than the ‘N’ times and less than or equal to ‘2N’ times, the memory device 300 may generate the reverse current IRD_R that flows in the other direction through the selected memory cell according to the reverse operation in step S110. For example, the memory device 300 may generate the reverse current IRD_R according to the reverse read operation while performing the read operation on the selected memory region between 201 times and 400 times (i.e., ‘N’ is ‘200’).

During the reverse read operation, the read circuit 380 may compare the reverse current IRD_R with the reference current IREF and generate the read data RD_DATA corresponding to the comparison result. During the reverse read operation, a composition ratio of the selection element layer included in the selected memory cell is recognized as reversed due to the reverse current IRD_R flowing in the other direction, and thus the read data RD_DATA has to be inverted. For example, when the selected memory cell has a threshold voltage corresponding to the high resistance state (e.g., the RESET state), the position of the selection element layer included in the selected memory cell, specifically the upper and lower portions, may change based on the direction of the reverse current IRD_R during the reverse read operation. As a result, the selected memory cell may be recognized as having a threshold voltage corresponding to the low resistance state (e.g., the SET state). Accordingly, during the reverse read operation, the read data RD_DATA may unintentionally exhibit an inverted data value, necessitating its inversion. Although not illustrated, the inversion of the read data RD_DATA may be performed by either the memory device 300 or the control device 200, depending on the design configuration, during the reverse read operation.

When it is determined in step S112 that the read count information RD_NUM for the selected memory region reaches ‘2N’ times (or ‘2N’ times or more), the control device 200 may initialize or reset read count information for the selected memory region among the read count information RD_NUM in step S114. For example, the control device 200 may initialize the read count information for the selected memory region to an initial value, such as ‘0,’ after the 400^{th} read operation is performed on the selected memory region.

In step S112, when the read count information RD_NUM for the selected memory region is less than ‘2N’ times, the process goes to step S116 to determine whether the memory system 10 exits the read mode.

When it is determined in the step S116 that the memory system 10 does not exit the read mode, the above-described processes S102 to S114 may be repeatedly performed until the memory system 10 exits the read mode in step S116.

FIG. 6 is a simplified diagram for describing the forward read operation.

Referring to FIG. 6, when the forward current IRD_F flows according to the forward read operation, the high voltage VH may be supplied to one end of the memory cell MC, and the low voltage VL may be supplied to the other end of the memory cell MC. For example, during the forward read operation, the one end of the memory cell MC may be coupled to the output terminal of the high voltage VH through the first coupling portion M1, while the other end of the memory cell MC may be coupled to the output terminal of the low voltage VL through the fourth coupling portion M4. Accordingly, the forward current IRD_F may flow in the forward direction, that is, in the one direction, through the memory cell MC.

When the forward read operation is repeated, the memory cell MC may be subjected to read stress due to the repeated generation of the forward current IRD_F. As a result, the threshold voltage of the memory cell MC may unintentionally vary due to the read stress. For example, even though the memory cell MC normally has a threshold voltage corresponding to the high resistance state (i.e., intended threshold voltage), the memory cell MC may unintentionally exhibit a threshold voltage corresponding to the low resistance state (i.e., unintended threshold voltage) due to the read stress accumulated after repeated forward read operations. This change is related to a shift in the composition ratio of materials included in the selection element layer.

FIG. 7 is a simplified diagram for describing the reverse read operation.

Referring to FIG. 7, when the reverse current IRD_R flows according to the reverse read operation, the low voltage VL may be supplied to the one end of the memory cell MC, and the high voltage VH may be supplied to the other end of the memory cell MC. For example, during the reverse read operation, the one end of the memory cell MC may be coupled to the output terminal of the low voltage VL through the second coupling portion M2, while the other end of the memory cell MC may be coupled to the output terminal of the high voltage VH through the third coupling portion M3. Accordingly, the reverse current IRD_R may flow in the reverse direction, that is, in the other direction, through the memory cell MC.

When the reverse read operation is repeatedly performed, the threshold voltage of the memory cell MC may return to its normal state, even though it was unintentionally changed. In other words, the composition ratio of the materials included in the selection element layer may be restored to its original condition.

According to an embodiment of the present disclosure, a forward read operation and a reverse read operation may be alternately performed according to a read count in a read mode, which makes it possible to suppress read disturbance.

According to an embodiment of the present disclosure, the read disturbance may be suppressed, which makes it possible to improve operational reliability in the read mode.

While the present disclosure has been illustrated and described with respect to specific embodiments, the disclosed embodiments are provided for the description, and not intended to be restrictive. Further, it is noted that the embodiments of the present disclosure may be achieved in various ways through substitution, change, and modification that fall within the scope of the following claims, as those skilled in the art will recognize in light of the present disclosure. The embodiments may be combined to form additional embodiments.

What is claimed is:

1. A memory device, comprising:
a memory cell array including a plurality of memory cells;
a first voltage selection circuit suitable for supplying one of a high voltage and a low voltage to one end of the memory cell array in response to a flag signal indicating a forward read operation or a reverse read operation in a read mode, a logic value of the flag signal being determined based on read count information;
a second voltage selection circuit suitable for supplying the other voltage of the high voltage and the low voltage to the other end of the memory cell array in response to the flag signal in the read mode; and
a read circuit coupled to one of the one end and the other end of the memory cell array and suitable for reading data stored in a memory cell selected from the plurality of memory cells in the read mode.

2. The memory device of claim 1, wherein in the read mode, a cell current flows through the selected memory cell, and the cell current flows in a first direction through the selected memory cell according to the forward read operation and flows in a second direction through the selected memory cell according to the reverse read operation, the first direction being opposite to the second direction.

3. The memory device of claim 1, wherein the read count information is tracked for each memory region within the memory cell array.

4. The memory device of claim 3, wherein the memory region corresponds a page or block within the memory cell array.

5. The memory device of claim 1, further comprising:
a buffer memory suitable for storing the read count information based on address information corresponding to the selected memory cell; and
a read control circuit suitable for updating the read count information according to a read command signal and generate the flag signal based on the read count information.

6. The memory device of claim 5, wherein the buffer memory is integrated within the memory cell array or configured separately from the memory cell array.

7. The memory device of claim 5, wherein the read control circuit generates the flag signal corresponding to the forward read operation when the read count information is N times or less (where N is a natural number greater than or equal to 1), generates the flag signal corresponding to the reverse read operation when the read count information is greater than N but 2N times or less, and resets the read count information when the read count information reaches 2N times.

8. A memory system, comprising:
a control device suitable for generating a flag signal indicating a forward read operation or a reverse read operation based on read count information; and
a memory device suitable for changing a direction of a cell current flowing through a memory cell selected from a plurality of memory cells within a memory cell array, according to the forward read operation or the reverse read operation, and outputting read data corresponding to the cell current to the control device, based on the flag signal and a read command signal.

9. The memory system of claim 8, wherein the read count information is updated or initialized according to a number of times the read command signal is generated in a read mode.

10. The memory system of claim 8, wherein the read count information is tracked for each memory region within the memory cell array.

11. The memory system of claim 10, wherein the memory region corresponds to a page or block within the memory cell array.

12. The memory system of claim 8, further comprising a buffer memory device suitable for storing the read count information, and
wherein the control device updates the read count information according to the read command signal.

13. The memory system of claim 12, wherein the control device generates the flag signal corresponding to the forward read operation when the read count information is N times or less (where N is a natural number greater than or equal to 1), generates the flag signal corresponding to the reverse read operation when the read count information is greater than N but 2N times or less, and resets the read count information when the read count information reaches 2N times.

14. The memory system of claim 8, wherein the memory device includes:
a memory cell array including the plurality of memory cells;
a first voltage selection circuit suitable for supplying one of a high voltage and a low voltage to one end of the memory cell array in response to the flag signal in a read mode;
a second voltage selection circuit suitable for supplying the other voltage of the high voltage and the low voltage to the other end of the memory cell array in response to the flag signal in the read mode; and
a read circuit coupled to one of the one end and the other end of the memory cell array and suitable for reading data stored in the selected memory cell in the read mode.

15. The memory system of claim 8, wherein in the read mode, the cell current flows in a first direction through the selected memory cell according to the forward read operation and flows in a second direction through the selected memory cell according to the reverse read operation, the first direction being opposite to the second direction.

16. An operating method of a memory system, the operating method comprising:
causing a cell current to flow in a first direction through a memory cell selected from a plurality of memory cells in a memory cell array, according to a forward read operation when read count information corresponding to the selected memory cell is N times or less (where N is a natural number greater than or equal to 1);
causing the cell current to flow in a second direction through the selected memory cell according to a reverse read operation when the read count information corresponding to the selected memory cell is greater than N but 2N times or less, the first direction being opposite to the second direction; and
reading data stored in the selected memory cell based on the cell current and a reference current.

17. The operating method of claim 16, wherein causing the cell current to flow in the first direction includes supplying a high voltage to one end of the selected memory cell and supplying a low voltage to the other end of the selected memory cell.

18. The operating method of claim 17, wherein causing the cell current to flow in the second direction includes supplying the low voltage to the one end of the selected memory cell and supplying the high voltage to the other end of the selected memory cell.

19. The operating method of claim 16, wherein the read count information is updated or reset according to a read count of a memory region to which the selected memory cell belongs among memory regions in the memory cell array in a read mode.

20. The operating method of claim 16, further comprising resetting the read count information when the read count information corresponding to the selected memory cell reaches 2N times.
